(19) United States
(12) Patent Application Publication
(10) Pub. No.: US 2026/0122916 A1
(43) Pub. Date: Apr. 30, 2026

(54) CROSSBAR CIRCUITS INCORPORATING 2-TRANSISTOR-2-RESISTOR CONFIGURATIONS

(71) Applicant: TetraMem Inc., Fremont, CA (US)

(72) Inventors: Minxian Zhang, Amherst, MA (US); Ning Ge, Danville, CA (US)

(73) Assignee: TetraMem Inc., Fremont, CA (US)

(21) Appl. No.: 18/933,973

(22) Filed: Oct. 31, 2024

(51) Int. Cl. H10B 63/00; G11C 7/16

(52) U.S. Cl. CPC H10B 63/80; G11C 7/16; H10B 63/30

(57) ABSTRACT

An apparatus may include a plurality of bit lines, a plurality of word lines, a plurality of source lines, and a plurality of cross-point devices connecting to the bit lines, the word lines, and the source lines. A first cross-point device of the plurality of cross-point devices is connected to a first bit line and a second bit line of the plurality of bit lines, a first word line of the plurality of word lines, and a first source line of the plurality of source lines. The first cross-point device may include a first RRAM device, an NMOS transistor connected to the first RRAM device, a PMOS transistor connected to the NMOS transistor, and a second RRAM device connected to the PMOS transistor. The NMOS transistor and the PMOS transistor are connected to the first source line and can be arranged in a side-by-side structure or a stacked-up structure.

### TECHNICAL FIELD

The implementations of the disclosure generally relate to electronic circuits and, more specifically, to crossbar circuits incorporating 2-transistor-2-resistors (2T2R) configurations using complementary NMOS (N-type Metal-Oxide-Semiconductor) and PMOS (P-type Metal-Oxide-Semiconductor) transistor pairs.

### BACKGROUND

A crossbar circuit may refer to a circuit structure with interconnecting electrically conductive lines sandwiching a memory element, such as a resistive switching material, at their intersections. The resistive switching material may include, for example, a memristor (also referred to as resistive random-access memory (RRAM or ReRAM)). Crossbar circuits may be used to implement in-memory computing applications, non-volatile solid-state memory, image processing, neural networks, etc.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

According to one or more aspects of the present disclosure, a crossbar circuit including a 2T2R configuration is provided. In some embodiments, the crossbar circuit includes a plurality of bit lines; a plurality of word lines; a plurality of source lines; and a plurality of cross-point devices connecting to the plurality of bit lines, the plurality of word lines, and the plurality of source lines. A first cross-point device of the plurality of cross-point devices is connected to a first bit line and a second bit line of the plurality of bit lines, a first word line of the plurality of word lines, and a first source line of the plurality of source lines. The first cross-point device includes a first RRAM device; an NMOS transistor connected to the first RRAM device; a PMOS transistor connected to the NMOS transistor; and a second RRAM device connected to the PMOS transistor. The NMOS transistor and the PMOS transistor are connected to the first source line.

In some embodiments, a source terminal of the NMOS transistor and a drain terminal of the PMOS transistor are connected to the first source line.

In some embodiments, a first terminal of the first RRAM device is connected to a first bit line, wherein a second terminal of the first RRAM device is connected to the NMOS transistor.

In some embodiments, the second terminal of the first RRAM device is connected to a first drain terminal of the NMOS transistor.

In some embodiments, a second terminal of the second RRAM device is connected to the PMOS transistor.

In some embodiments, the second terminal of the second RRAM device is connected to a source of the PMOS transistor.

In some embodiments, a first terminal of the second RRAM device is connected to the second bit line.

In some embodiments, a first gate terminal of the NMOS transistor and a second gate terminal of the PMOS transistor are connected to the first word line.

In some embodiments, the NMOS transistor and the PMOS transistor are vertically stacked on a substrate.

In some embodiments, the first source line is connected to an analog-to-digital converter (ADC).

In some embodiments, an apparatus is provided. The apparatus includes a first subarray of RRAM devices; a plurality of NMOS transistors connected to a first plurality of bit lines, wherein each of the first subarray of RRAM devices is connected to one of the plurality of NMOS transistors; a second subarray of RRAM devices; a plurality of PMOS transistors connected to a second plurality of bit lines; and a plurality of word lines. Each of the second subarray of RRAM devices is connected to one of the plurality of PMOS transistors. Each of the word lines is connected to one of the plurality of NMOS transistors and one of the plurality of PMOS transistors.

In some embodiments, the apparatus further includes a plurality of source lines connected to the plurality of NMOS transistors and the plurality of PMOS transistors, wherein a first NMOS transistor and a first PMOS transistor are connected to a first source line of the plurality of source lines.

In some embodiments, a source terminal of the first NMOS transistor is connected to a drain terminal of the first PMOS transistor.

In some embodiments, the first NMOS transistor is connected to a first RRAM device of the first subarray of RRAM devices. In some embodiments, the first PMOS transistor is connected to a second RRAM device of the second subarray of RRAM devices.

In some embodiments, the first NMOS transistor is connected to a first bit line of the first plurality of bit lines. In some embodiments, the first PMOS transistor is connected to a second bit line of the second plurality of bit lines.

In some embodiments, a first gate terminal of the first NMOS transistor and a second gate terminal of the first PMOS transistor are connected to a first word line of the plurality of word lines.

In some embodiments, the apparatus further includes a plurality of analog-to-digital converters connected to the plurality of source lines, wherein the first source line is connected to a first analog-to-digital converter of the plurality of analog-to-digital converters.

In some embodiments, the apparatus further includes a word line logic configured to provide a positive voltage to the plurality of NMOS transistors to selectively activate one or more of the plurality of NMOS transistors.

In some embodiments, the word line logic is further configured to provide a negative voltage to the plurality of PMOS transistors to selectively activate one or more of the plurality of PMOS transistors.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding.

FIG. 1A is a schematic diagram illustrating an example cross-point device in a 1-transistor-1-resistor (1T1R) configuration in accordance with some embodiments of the present disclosure.

FIG. 1B is a schematic diagram illustrating a prior art 2-transistor-2-resistor (2T2R) configuration.

FIG. 1C is a schematic diagram illustrating an example cross-point device in a 2-transistor-2-resistor (2T2R) configuration in accordance with some embodiments of the present disclosure.

FIG. 2 is a circuit diagram illustrating an example crossbar circuit in accordance with some embodiments of the present disclosure.

FIG. 3A is a schematic diagram illustrating an example 2T2R configuration NMOS and PMOS transistor pairs arranged side-by-side on a substrate in accordance with some embodiments of the present disclosure.

FIG. 3B is a schematic diagram illustrating an example 2T2R configuration including NMOS and PMOS transistor pairs arranged in a 3D vertical structure in accordance with some embodiments of the present disclosure.

FIG. 4 is a schematic diagram illustrating a cross-sectional view of an example RRAM device in accordance with some embodiments of the present disclosure.

### DETAILED DESCRIPTION

Aspects of the disclosure provide crossbar circuits incorporating two-transistor-two-resistor (2T2R) configurations. The 2T2R configuration may include complementary NMOS and PMOS transistor pairs. In some embodiments, the complementary NMOS and PMOS transistor pairs can be arranged side-by-side on a substrate, such as in a planar field-effect transistor (planar FET), Fin field-effect transistor (FinFET), or gate-all-around FET (GAAFET) configuration. In some embodiments, the complementary NMOS and PMOS transistor pairs may be arranged in a 3D vertical structure, such as a complementary field-effect transistor (CFET) structure. A crossbar circuit may include intersecting electrically conductive wires (e.g., row lines, column lines, etc.) and cross-point devices arranged in one or more arrays. Each of the cross-point devices may be connected to a word line, a bit line, and a select line. The cross-point devices may include, for example, a phase-change memory (PCM) device, a floating gate device, a spintronic device, a ferroelectric device, an RRAM device, etc. The crossbar circuits may be used for multi-level memory (MLM) circuits and in-memory computing (IMC) circuits.

Conventional crossbar circuits typically utilize an NMOS (n-type metal-oxide-semiconductor) transistor to implement 1T1R (one-transistor-one-resistor) or 2T2R (two-transistor-two-resistor) configurations. An NMOS transistor turns on when its gate voltage is higher than the source voltage by at least a positive threshold voltage. The threshold voltage for an NMOS transistor is positive. In contrast, a PMOS (p-type metal-oxide-semiconductor) transistor turns on when the gate voltage is lower than the source voltage by at least the threshold voltage. The threshold voltage for PMOS transistors is negative.

The present disclosure provides 2T2R configurations that include both NMOS and PMOS transistors and crossbar circuits incorporating the 2T2R configurations. In some embodiments, a 2T2R configuration may include a first RRAM device, an NMOS transistor, a PMOS transistor, and a second RRAM device that are electrically connected to each other. As an example, the first RRAM device may be connected between a first bit line and the drain terminal of the NMOS transistor. The second RRAM device may be connected between a second bit line and the source terminal of the PMOS transistor. The gate terminal of the NMOS transistor and the gate terminal of the PMOS transistor may be connected to a word line. The source terminal of the NMOS transistor and the drain terminal of the PMOS transistor may be connected to a source line and to an analog-to-digital converter (ADC) via the source line. When a positive voltage greater than the threshold voltage of the NMOS transistor is applied to the word line, the NMOS transistor turns on. The first RRAM device may thus be activated for programming and/or in-memory computing. When a negative voltage greater than the threshold voltage of the PMOS transistor is applied to the word line, the PMOS transistor turns on. The second RRAM device may thus be activated for programming and/or in-memory computing.

In some embodiments, a crossbar circuit may include multiple intersecting word lines, bit lines, and source lines. The crossbar circuit may further include a plurality of cross-point devices formed at the intersections of the word lines, the bit lines, and the source lines. Each of the cross-point devices may include a 2T2R configuration as described herein. Each of the cross-point devices may be connected to one word line, two bit lines, and one source line. When a positive word line (WL) voltage is applied to a word line, the NMOS transistors connected to the word line may be turned on. The RRAM devices connected to the NMOS transistors may thus be activated for programming and/or in-memory computing. When a negative WL voltage is applied to the word line, the PMOS transistors connected to the word line may be turned on. The RRAM device connected to the PMOS transistors may thus be activated for programming and/or in-memory computing. As such, the crossbar circuit may implement two crossbar arrays, one crossbar subarray controlled by NMOS transistors and one crossbar subarray controlled by PMOS transistors. These subarrays share the same source lines and word lines but may operate independently of each other. These crossbar arrays may be used for different vector-matrix multiplication (VMM) operations. Both NMOS and PMOS transistors can share the same source line for VMM output, and they can also share the same analog-to-digital converter (ADC), which reduces hardware redundancy, optimizes circuit performance, and reduces circuit space.

In some embodiments, a 2T2R configuration described herein may be implemented using a complementary field-effect transistor (CFET) structure. The CFET structure may include a PMOS transistor and an NMOS transistor stacked vertically on a substrate. The two transistors share a single transistor's footprint, as they are vertically stacked, effectively reducing the layout area. In some embodiments, a CFET structure may include an NMOS transistor stacked on top of a PMOS transistor. In some embodiments, a CFET may include two NMOS transistors stacked on top of two PMOS transistors. This vertical ‘folding’ of NMOS and PMOS transistors eliminates the n-to-p separation bottleneck, thereby reducing the cell's active area footprint. The CFET structure results in a taller stack of PMOS and NMOS transistors. Half of the stack may be used for one transistor, and the other half for the other transistor, enabling a 2T configuration from the vertical stack. Since CFET can provide two complementary transistors within the footprint of a single device, and the 2T2R memristor crossbar array reduces the number of source lines (SL) by half, the CFET 2T2R configuration can achieve high device density and high performance. This configuration offers numerous advantages in terms of compactness and efficiency.

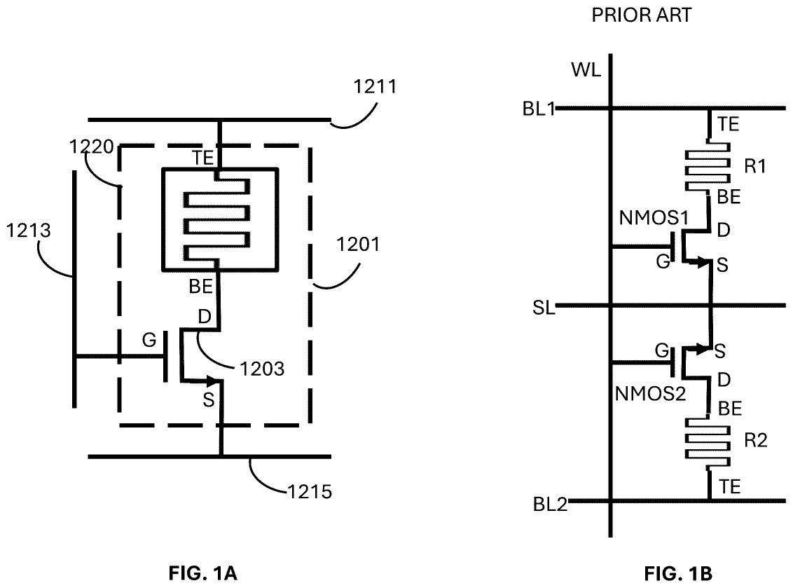

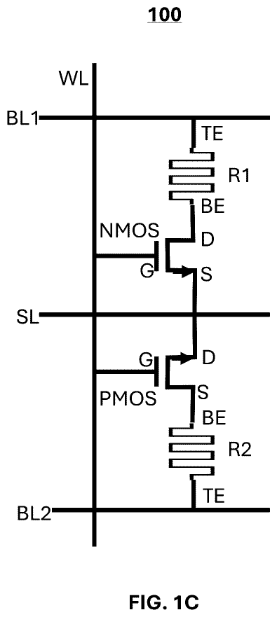

FIG. 1A is a schematic diagram illustrating an example cross-point device 1220 in a 1-transistor-1-resistor (1T1R) configuration in accordance with some embodiments of the present disclosure.

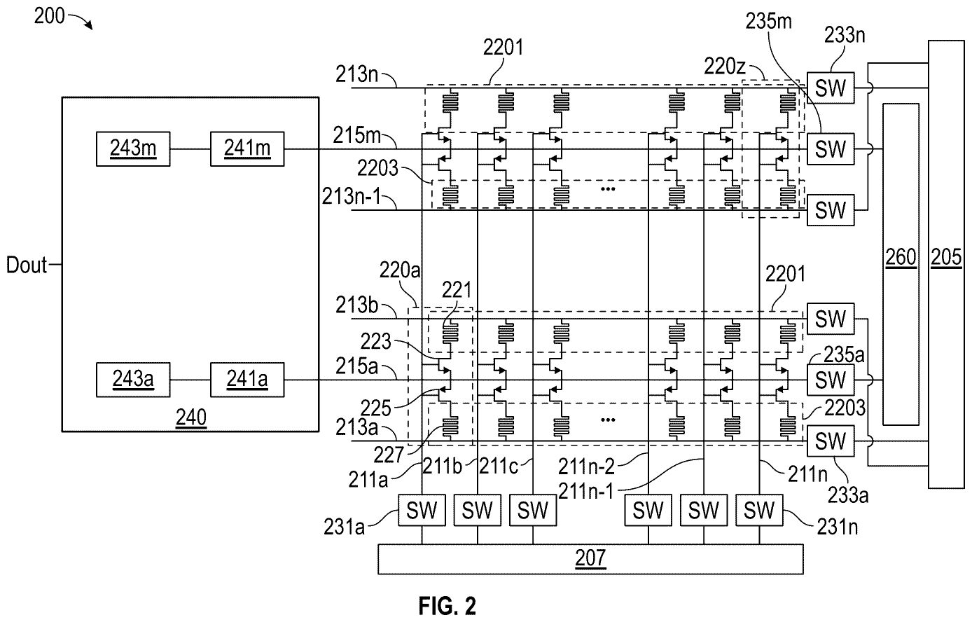

As shown, cross-point device 1220 may include an RRAM device 1201 and a transistor 1203 that are connected in series. A transistor may include three terminals that may be marked as gate (G), source(S), and drain (D), respectively. A first terminal of RRAM device 1201 may be connected to the drain of transistor 1203. A second terminal of RRAM device 1201 may be connected to a bit line 1211. The source of the transistor 1203 may be connected to a source line 1215. The gate of transistor 1203 may be connected to a select line 1213. Select line 1213 may be a word line of FIG. 2.

Transistor 1203 may function as a selector as well as a current controller and may set the current compliance for RRAM device 1201 during programming. The gate voltage on transistor 1203 can set current compliance for cross-point device 1220 during programming and can thus control the conductance and analog behavior of cross-point device 1220. For example, when cross-point device 1220 is set from a high-resistance state to a low-resistance state, a set signal (e.g., a voltage signal, a current signal) may be provided via bit line 1211 or source line 1215. Another voltage, also referred to as a select voltage or gate voltage, may be applied via select line 1213 to the transistor gate to open the gate and set the current compliance, while source line 1215 or bit line 1211 may be grounded. When cross-point device 1220 is reset from the low-resistance state to the high-resistance state, a gate voltage may be applied to the gate of transistor 1203 via select line 1213 to open the transistor gate. Meanwhile, a reset signal may be sent to RRAM device 1201 via source line 1215 (or bit line 1211), while bit line 1211 (or source line 1215) may be grounded.

FIG. 1B is a schematic diagram illustrating a prior art 2-transistor-2-resistor (2T2R) configuration. As shown, the 2T2R configuration may include a first RRAM device R1, two NMOS transistors (NMOS1 and NMOS2), and a second RRAM device R2 that are electrically connected to each other. As an example, the first RRAM device may be connected between a first bit line BL1 and the drain terminal of the first NMOS transistor NMOS1. The second RRAM device R2 may be connected between a second bit line BL2 and the drain terminal of the second NMOS transistor NMOS2. The gate terminal of the first NMOS transistor NMOS1 and the gate terminal of the second NMOS transistor NMOS2 may be connected to a word line WL. The source terminal of the first NMOS transistor and the source terminal of the second NMOS transistor may be connected to a source line and to an analog-to-digital converter (ADC) via the source line. When a positive voltage greater than the threshold voltage of the NMOS transistor is applied to the word line, the two NMOS transistors turn on. Since both gate terminals of NMOS1 and NMOS2 are connected to the same word line WL, they are activated simultaneously and cannot be switched on or off individually. When a bit line voltage is applied between the first bit line BL1 and the source line, the first RRAM device may thus be activated for programming and/or in-memory computing. When a bit line voltage is applied between the second bit line BL2 and the source line, the second RRAM device may thus be activated for programming and/or in-memory computing.

FIG. 1C is a schematic diagram illustrating an example 100 of a 2-transistor-2-resistor (2T2R) configuration using a complementary NMOS and PMOS transistor pair in accordance with some embodiments of the present disclosure.

As shown, 2T2R configuration 100 may include a first RRAM device, an NMOS transistor, a PMOS transistor, and a second RRAM device that are electrically connected to each other. As an example, the first RRAM device may be connected between a first bit line BL1 and the drain terminal of the NMOS transistor. The second RRAM device may be connected between a second bit line BL2 and the source terminal of the PMOS transistor. The gate terminal of the NMOS transistor and the gate terminal of the PMOS transistor may be connected to a word line. The source terminal of the NMOS transistor and the drain terminal of the PMOS transistor may be connected to a source line and an analog-to-digital converter (ADC) via the source line. When a positive voltage that is greater than the threshold voltage of the NMOS transistor is applied to the word line, the NMOS transistor turns on while the PMOS transistor turns off. When a bit line voltage is applied between the first bit line BL1 and the source line, the first RRAM device may thus be activated for programming and/or in-memory computing. When a negative voltage that is greater than the threshold voltage of the PMOS transistor is applied to the word line, the PMOS transistor turns on while the NMOS transistor turns off. When a bit line voltage is applied between the second bit line BL2 and the source line, the second RRAM device may thus be activated for programming and/or in-memory computing.

FIG. 2 is a circuit diagram illustrating an example crossbar-based apparatus 200 in accordance with some embodiments of the present disclosure.

As shown, crossbar-based apparatus 200 may include word lines 211a, 211b, 211c, . . . , 211n-2, 211n-1, and 211n, bit lines 213a, 213b, . . . , 213n-2, 213n-1, 213n, and source lines 215a, . . . , 215m. In some embodiments, the number of source lines may be half the number of word lines or bit lines in crossbar-based apparatus 200.

Each word line 211a-211n may be connected to a column switch 231a, . . . , 231n. Each column switch 231a-231n may include any suitable circuit structure that may control the current flowing through word lines 211a-211n. Each bit line 213a-213n may be connected to a row switch 233a, . . . , 233n. Each column switch 233a-233n may include any suitable circuit structure that may control the current passing through bit lines 213a-213n. Each source line 235a-235m may be connected to a switch 235a, . . . , 235m. In some embodiments, one or more of switches 231a-n, 233a-n, 235a-m may further provide fault protection, electrostatic discharge (ESD) protection, noise reduction, and/or any other suitable function for one or more portions of crossbar-based apparatus 200. For example, column switches 231a-231n, row switches 233a-233n, and row switches 235a-235m may be and/or include a CMOS switch circuit.

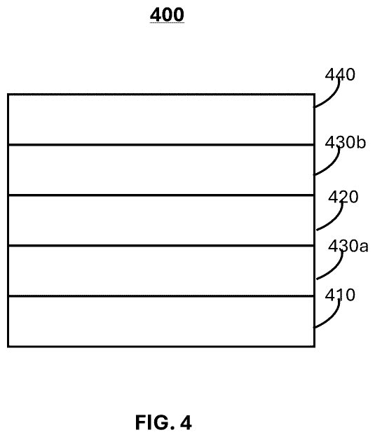

Crossbar-based apparatus 200 may further include cross-point devices 220a, 220b, . . . , 220z connecting to the intersections of the word lines, the bit lines, and the source lines. Each cross-point device 220a, 220b, . . . , 220z may include two transistors and two RRAM devices that are electrically connected in sequence (also referred to as a “2T2R” configuration). Each cross-point device 220a-220z may be connected to a word line, two bit lines, and a source line. For example, a first cross-point device 220a may be connected to a first word line 211a, a first bit line 213a, a second bit line 213b, and a first source line 215a. First cross-point device 220a may include a first RRAM device 221, an NMOS transistor 223, a PMOS transistor 225, and a second RRAM device 227. In some embodiments, the combination of first RRAM device 221 and NMOS transistor 223 and/or the combination of second RRAM device 227 and PMOS transistor 225 may be a 1T1R configuration as described in connection with FIG. 1A. Each first cross-point 220a-220z may include a 2T2R configuration as described in connection with FIG. 1C above. Each RRAM device in cross-point devices 220a-220z may include an RRAM device as described in connection with FIG. 4 below.

As shown in FIG. 2, NMOS transistor 223 is connected to first RRAM device 221. PMOS transistor 225 is connected to NMOS transistor 223. Second RRAM device 227 is connected to PMOS transistor 225. Both NMOS transistor 223 and PMOS transistor 225 are connected to first source line 215a. In some embodiments, the source terminal of NMOS transistor 223 (also referred to as the “first source terminal”) and the drain terminal of PMOS transistor 225 (also referred to as the “second drain terminal”) are connected to first source line 215a.

A first terminal of first RRAM device 221 is connected to first bit line 213b. A second terminal of first RRAM device 221 (e.g., the bottom terminal of first RRAM device 221) may be connected to NMOS transistor 223. In some embodiments, the second terminal of first RRAM device 221 may be connected to the drain terminal of NMOS transistor 223 (also referred to as the “first drain terminal”). In some embodiments, the first terminal and the second terminal of first RRAM device 221 may be the top terminal and the bottom terminal of first RRAM device 221, respectively.

As shown, a second terminal of second RRAM device 227 is connected to the source terminal of PMOS transistor 225 (also referred to as the “second source terminal”). A first terminal of second RRAM device 227 may be connected to second bit line 213a. In some embodiments, the first terminal and the second terminal of second RRAM device 227 may be the top terminal and the bottom terminal of second RRAM device 227, respectively.

In some embodiments, the first RRAM device and/or the second RRAM device may be replaced by a phase-change memory (PCM) device, a floating gate, a spintronic device, a ferroelectric device, or any other suitable device with programmable resistance.

Crossbar-based apparatus 200 may also include output sensor(s) 240 that may convert the current flowing through source lines 215a-215m into an output signal (Dout). For example, output sensor(s) 240 may include one or more readout circuits 241a-241m. Each readout circuit 241a-241m may include a trans-impedance amplifier (TIA) or any other suitable component that may convert the current flowing through a respective source line into a respective voltage signal. Output sensor(s) 240 may further include one or more analog-to-digital converters (ADCs) 243a-243m that may convert the analog signal into a digital output. In some embodiments, output sensor(s) 240 may further include one or more multiplexers (not shown). In some embodiments, the current flowing through the respective source line may be directly converted to a digital output without being converted to an intermediate voltage.

As shown in FIG. 2, the first and second RRAM devices in a 2T2R configuration may share the same source line and ADC. The number of source lines may be half that of the bit lines in crossbar-based apparatus 200. Unlike conventional crossbar circuits that require at least n ADCs to implement an n×n crossbar array, crossbar-based apparatus 200 may utilize n/2 ADCs to implement an n×n crossbar array. This may significantly reduce the number of ADCs required, leading to potential cost savings and lower power consumption.

A voltage (also referred to as a WL voltage) may be applied to one or more word lines 211a-211n to program one or more RRAM devices in crossbar-based apparatus 200. As an NMOS transistor and a PMOS transistor are connected to the same word line and may be turned on by threshold voltages of different polarities, the WL voltage of a particular polarity may turn on either the NMOS transistor or the PMOS transistor. When a positive WL voltage is applied to a word line, the NMOS transistors connected to the word line may be activated. As a result, the RRAM devices connected to the NMOS transistors (also referred to as the first subarray of RRAM devices 2201) may be activated for programming and/or in-memory computing. When a negative WL voltage is applied to the word line, the PMOS transistors connected to the word line may be activated. As a result, the RRAM devices connected to the PMOS transistors (also referred to as the second subarray of RRAM devices 2203) may be activated for programming and/or in-memory computing. As such, the RRAM devices may function as two sub-crossbar arrays that may operate respectively based on the polarity of the word line voltage applied to the word lines. In particular, the RRAM devices connected to the NMOS transistors may form a first crossbar array that may be activated in response to the application of a positive WL voltage. The RRAM devices connected to the PMOS transistors may form a second crossbar array that may be activated in response to the application of a negative WL voltage. As such, crossbar-based apparatus 200 may implement two crossbar arrays that may operate independently of each other. The crossbar arrays share the same source lines and ADCs.

Programming circuit 260 may program the activated RRAM devices to suitable conductance values. For example, programming a cross-point device may involve applying a suitable voltage signal or current signal across the RRAM device (e.g., via a word line voltage to control the NMOS transistor or PMOS transistor that is connected to the RRAM device, and a bit line voltage or a source line voltage applied across the RRAM device). Programming circuit 260 may program one or more activated RRAM devices by applying a suitable programming voltage on the bit line(s) connected to the activated RRAM devices. The activated RRAM devices may be programmed to conductance values corresponding to the programming voltage. Programming circuit 260 may include any suitable voltage generator. Setting an RRAM device may involve reducing the resistance of the cross-point device. Resetting the RRAM device may involve increasing the resistance of the RRAM device.

WL logic 207 may include any suitable component for generating and/or providing voltages to word lines 211a-211n. For example, WL logic 207 may include drivers, voltage generators, decoders, multiplexers, etc. Each word line 211a-211n may be connected to WL logic 207 via a respective column switch 231a-231n.

BL logic 205 may include any suitable component for generating and/or providing input signals to selected cross-point devices via bit lines. For example, BL logic 205 may include one or more digital-to-analog converters (DACs), amplifiers, etc. Each of the input signals may be a voltage signal, a current signal, etc.

Crossbar-based apparatus 200 may perform parallel weighted voltage multiplication and current summation. For example, an input voltage signal may be applied to one or more bit lines of crossbar-based apparatus 200 (e.g., one or more selected bit lines). The input signal may flow through the activated RRAM devices connected to the bit lines. The conductance of each of the activated RRAM devices may be programmed to a specific value (also referred to as a “weight”). By Ohm's law, the input voltage multiplies the cross-point conductance and generates a current from the RRAM device. By Kirchhoff's law, the sum of the currents passes through the activated RRAM devices on a respective source line (also referred to as the “source line current”), which may be read by an output sensor 240. According to Ohm's law and Kirchhoff's current law, the input-output relationship of the crossbar array can be represented as I=VG, wherein I represents the output signal matrix as current; V represents the input signal matrix as voltage; and G represents the conductance matrix of the activated RRAM devices. As such, the input signal is weighted at each of the cross-point devices by its conductance according to Ohm's law. The weighted current (the “source line current”) is output via each source line and may be accumulated according to Kirchhoff's current law. This may enable in-memory computing (IMC) via parallel multiplications and summations performed in the crossbar arrays.

Crossbar-based apparatus 200 may be configured to perform vector-matrix multiplication (VMM). A VMM operation may be represented as Y=XA, wherein each of Y, X, A represents a respective matrix. More particularly, for example, input vector X may be mapped to the input voltage V of crossbar-based apparatus 200. Matrix A may be mapped to conductance values G of the activated RRAM devices. The output current I may be read and mapped back to output results Y. In some embodiments, crossbar-based apparatus 200 may be configured to implement a portion of a neural network by performing VMMs.

As described above, when a given word line voltage is applied to a word line, either the first crossbar array or the second crossbar array is active, while the other crossbar array is inactive. The selective operation of the crossbar arrays may reduce noise generated by the inactive crossbar array during operations. In some embodiments, the first crossbar array and the second crossbar array may be programmed to implement different applications (e.g., different inferencing tasks). For example, the first crossbar array and the second crossbar array may be programmed for continuous monitoring or screening if an event occurs, while the second crossbar array may be used to verify the nature of that event. This allows the system to operate efficiently, with one array continuously performing inference tasks, while the other is selectively engaged only when necessary for verification. In some embodiments, the first crossbar array may handle continuous inferencing tasks while the second crossbar array remains inactive. Conversely, the second crossbar array May be activated for selective inferencing when the first crossbar array detects an event, while the first crossbar array remains inactive to save power and minimize noise.

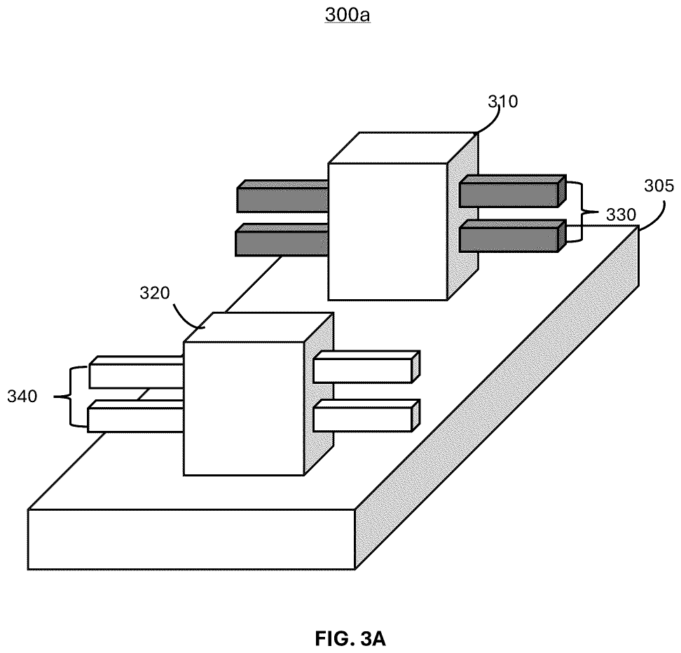

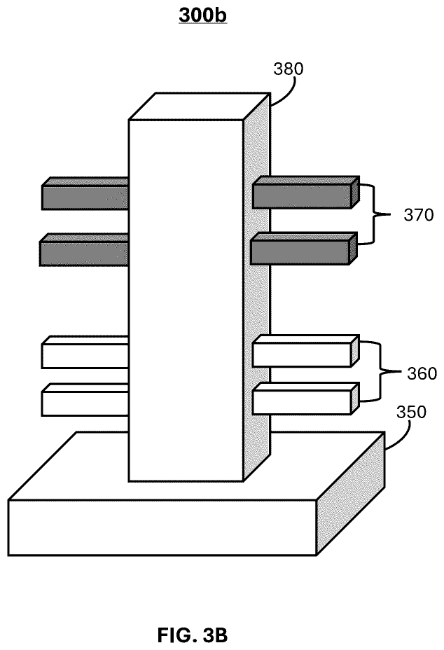

FIG. 3A is a schematic diagram illustrating an example 2T2R configuration 300a including NMOS and PMOS transistor pairs arranged side-by-side on a substrate in accordance with some embodiments of the present disclosure. The 2T2R configuration 300a may be a planar field-effect transistor (planar FET), Fin field-effect transistor (FinFET), or gate-all-around field-effect transistor (GAAFET). FIG. 3A schematically shows GAAFET NMOS and PMOS in a side-by-side structure.

As shown, 2T2R configuration 300a may include one or more NMOS transistors 330 and PMOS transistors 340 fabricated on a substrate 305. NMOS transistors 330 are vertically stacked on substrate 305. PMOS transistors 340 are vertically stacked on substrate 305. NMOS transistors 330 and PMOS transistors 340 are laterally arranged on substrate 305 in a side-by-side configuration.

NMOS transistors 330 may share a gate 310. Gate 310 may control the NMOS transistors' on/off states. When a positive voltage is applied to an NMOS transistor 330 through gate 310, current flows between the source and drain of the NMOS transistor.

PMOS transistors 340 may share a gate 320. Gate 320 may control the PMOS transistors' on/off states. When a negative voltage is applied to a PMOS transistor 340 through gate 320, current flows between the source and the drain of the PMOS transistor.

FIG. 3B is a schematic diagram illustrating an example 2T2R configuration 300b in a 3D vertical structure in accordance with some embodiments of the present disclosure. 2T2R configuration 300b may be a complementary field-effect transistor structure in some embodiments. 2T2R configuration 300b may include one or more PMOS transistors 360 and one or more NMOS transistors 370 vertically stacked on a substrate 350. In some embodiments, 2T2R configuration 300b may include an NMOS transistor and a PMOS transistor that form a vertical stack. In some embodiments, 2T2R configuration 300b may include two or more NMOS transistors stacked on top of two or more PMOS transistors.

NMOS transistors 360 and PMOS transistors 370 may share a gate 380. Gate 380 may control the transistor's on/off states. In NMOS transistors, current flows between the source and drain when a positive voltage is applied to the gate. In PMOS transistors, current flows between the source and drain when a negative voltage is applied to the gate.

In 2T2R configuration 300b, NMOS and PMOS transistors are stacked vertically. The vertical stacking of NMOS and PMOS transistors eliminates the n-to-p separation bottleneck, thereby reducing the cell's active area footprint. The CFET structure results in a taller stack of PMOS and NMOS transistors. Half of the stack may be used for one device, and the other half for the other device, enabling a 2T configuration from the vertical stack. Since CFET can provide two transistors within the footprint of a single device, and the 2T2R memristor crossbar array reduces the number of source lines (SL) by half, the CFET 2T2R configuration can achieve high device density, improved performance, and greater power efficiency.

FIG. 4 is a schematic diagram illustrating a cross-sectional view of an example RRAM device 400 in accordance with some embodiments of the present disclosure. As shown, RRAM device 400 may include a bottom electrode 410, a switching oxide layer 420, one or more interface layers 430a and 430b, and a top electrode 440. Interface layer 430a may be fabricated between bottom electrode 410 and switching oxide layer 420. Interface layer 430b may be fabricated between switching oxide layer 420 and top electrode 440.

Bottom electrode 410 may include a tantalum (Ta) adhesion layer and a noble metal such as platinum (Pt) or a conductive nitride layer. For example, the bottom electrode layer May include a Ta/Pt stack or other materials such as iridium (Ir), palladium (Pd), titanium nitride (TiN), tantalum nitride (TaN), etc.

Switching oxide layer 420 may include one or more transition metal oxides, such as TaOₓ, HfOₓ, TiOₓ, NbOₓ, ZrOₓ, etc., in binary oxides, ternary oxides, and high order oxides, wherein x indicates the oxide being oxygen deficient compared to its full (or terminal) oxide and the value of x may be varied from the oxygen to metal atomic ratio in the stoichiometry of its full oxides, such as x≤2.0 for HfOₓ (where HfO₂ is the full oxide), and x≤2.5 for TaOₓ (where Ta₂O₅ is the full oxide). As an example, switching oxide layer 420 may include Ta₂O₅. As another example, the switching oxide layer 420 may include HfO₂.

Top electrode 440 may include any suitable metallic material that is electronically conductive and reactive with the switching oxide. For example, the metallic material in top electrode 440 may include Ta, Hf, Ti, Ru, TiN, TaN, etc. Top electrode 440 may be reactive with the switching oxide and may have suitable oxygen solubility to adsorb some oxygen from the switching oxide and create oxygen vacancies in the switching oxide.

Each of interface layers 430a and 430b may be and/or include a film of a dielectric material that is more chemically stable than the transition metal oxide(s) in the switching oxide layer 420. As a result, the dielectric material may not react with the transition metal oxide(s) in the switching oxide layer 420. As an example, the transition metal oxide(s) of the switching oxide layer may be and/or include one or more transition metal oxides, such as at least one of HfOₓ or TaO_{y}, wherein x≤2.0, and wherein y≤2.5, and the dielectric material may include Al₂O₃, MgO, Y₂O₃, La₂O₃, etc.

The interface layers 430a and/or 430b may prevent excessive reactions between the RRAM switching oxide and the electrodes caused by additional thermal exposure to the RRAM device during the subsequent fabrication of interconnect layers on the RRAM device 400. In some embodiments, interface layer 430a and/or 430b may be omitted from RRAM device 400.

The terms “approximately,” “about,” and “substantially” as used herein may mean within a range of normal tolerance in the art, such as within 2 standard deviations of the mean, within +20% of a target dimension in some embodiments, within +10% of a target dimension in some embodiments, within +5% of a target dimension in some embodiments, within +2% of a target dimension in some embodiments, within +1% of a target dimension in some embodiments, and yet within +0.1% of a target dimension in some embodiments. The terms “approximately” and “about” may include the target dimension. Unless specifically stated or obvious from context, all numerical values described herein are modified by the term “about.”

As used herein, a range includes all the values within the range. For example, a range of 1 to 10 may include any number, combination of numbers, sub-range from the numbers of 1, 2, 3, 4, 5, 6, 7, 8, 9, and 10 and fractions thereof.

In the foregoing description, numerous details are set forth. It will be apparent, however, that the disclosure may be practiced without these specific details. In some instances, well-known structures and devices are shown in block diagram form, rather than in detail, in order to avoid obscuring the disclosure.

The terms “first,” “second,” “third,” “fourth,” etc. as used herein are meant as labels to distinguish among different elements and may not necessarily have an ordinal meaning according to their numerical designation.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Reference throughout this specification to “an implementation” or “one implementation” means that a particular feature, structure, or characteristic described in connection with the implementation is included in at least one implementation. Thus, the appearances of the phrase “an implementation” or “one implementation” in various places throughout this specification are not necessarily all referring to the same implementation.

As used herein, when an element or layer is referred to as being “on” another element or layer, the element or layer may be directly on the other element or layer, or intervening elements or layers may be present. In contrast, when an element or layer is referred to as being “directly on” another element or layer, there are no intervening elements or layers present.

Whereas many alterations and modifications of the disclosure will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the disclosure.

What is claimed is:

1. An apparatus, comprising:
a plurality of bit lines;
a plurality of word lines;
a plurality of source lines; and
a plurality of cross-point devices connecting to the plurality of bit lines, the plurality of word lines, and the plurality of source lines, wherein a first cross-point device of the plurality of cross-point devices is connected to a first bit line and a second bit line of the plurality of bit lines, a first word line of the plurality of word lines, and a first source line of the plurality of source lines, wherein the first cross-point device comprises:
a first RRAM device;
an NMOS transistor connected to the first RRAM device;
a PMOS transistor connected to the NMOS transistor; and
a second RRAM device connected to the PMOS transistor, wherein the NMOS transistor and the PMOS transistor are connected to the first source line.

2. The apparatus of claim 1, wherein a source terminal of the NMOS transistor and a drain terminal of the PMOS transistor are connected to the first source line, and wherein the first source line is connected to an analog-to-digital converter (ADC).

3. The apparatus of claim 2, wherein a first terminal of the first RRAM device is connected to a first bit line, and wherein a second terminal of the first RRAM device is connected to the NMOS transistor.

4. The apparatus of claim 3, wherein the second terminal of the first RRAM device is connected to a first drain terminal of the NMOS transistor.

5. The apparatus of claim 3, wherein a second terminal of the second RRAM device is connected to the PMOS transistor.

6. The apparatus of claim 5, wherein the second terminal of the second RRAM device is connected to a source of the PMOS transistor.

7. The apparatus of claim 5, wherein a first terminal of the second RRAM device is connected to the second bit line.

8. The apparatus of claim 2, wherein a first gate terminal of the NMOS transistor and a second gate terminal of the PMOS transistor are connected to the first word line.

9. The apparatus of claim 1, wherein the NMOS transistor and the PMOS transistor are horizontally side-by-side on a substrate.

10. The apparatus of claim 1, wherein the NMOS transistor and the PMOS transistor are vertically stacked on a substrate.

11. An apparatus, comprising:
a first subarray of RRAM devices;
a plurality of NMOS transistors connected to a first plurality of bit lines, wherein each of the first subarray of RRAM devices is connected to one of the plurality of NMOS transistors;
a second subarray of RRAM devices;
a plurality of PMOS transistors connected to a second plurality of bit lines, wherein each of the second subarray of RRAM devices is connected to one of the plurality of PMOS transistors; and
a plurality of word lines, wherein each of the word lines is connected to one of the plurality of NMOS transistors and one of the plurality of PMOS transistors.

12. The apparatus of claim 11, further comprising a plurality of source lines connected to the plurality of NMOS transistors and the plurality of PMOS transistors, wherein a first NMOS transistor and a first PMOS transistor are connected to a first source line of the plurality of source lines.

13. The apparatus of claim 12, wherein a source terminal of the first NMOS transistor is connected to a drain terminal of the first PMOS transistor.

14. The apparatus of claim 13, wherein the first NMOS transistor is connected to a first RRAM device of the first subarray of RRAM devices, and wherein the first PMOS transistor is connected to a second RRAM device of the second subarray of RRAM devices.

15. The apparatus of claim 13, wherein the first NMOS transistor is connected to a first bit line of the first plurality of bit lines, and wherein the first PMOS transistor is connected to a second bit line of the second plurality of bit lines.

16. The apparatus of claim 15, wherein a first gate terminal of the first NMOS transistor and a second gate terminal of the first PMOS transistor are connected to a first word line of the plurality of word lines.

17. The apparatus of claim 12, further comprising:
a plurality of analog-to-digital converters connected to the plurality of source lines, wherein the first source line is connected to a first analog-to-digital converter of the plurality of analog-to-digital converters.

18. The apparatus of claim 12, further comprising a word line logic configured to provide a positive voltage to the plurality of NMOS transistors to selectively activate one or more of the plurality of NMOS transistors.

19. The apparatus of claim 18, wherein the word line logic is further configured to provide a negative voltage to the plurality of PMOS transistors to selectively activate one or more of the plurality of PMOS transistors.

20. The apparatus of claim 19, further comprising a bit line logic configured to provide input signals to one or more of the first subarray of RRAM devices that are connected to the activated NMOS transistors or one or more of the second subarray of RRAM devices that are connected to the activated PMOS transistors.
